(19) United States
(12) Patent Application Publication
(10) Pub. No.: US 2025/0318124 A1
(43) Pub. Date: Oct. 9, 2025

(54) VERTICAL MEMORY DEVICES AND METHOD OF MANUFACTURING THE SAME

(71) Applicant: Samsung Electronics Co., Ltd., Suwon-si (KR)

(72) Inventors: Siyeong Yang, Suwon-si (KR); Seokhyun Kim, Suwon-si (KR); Yuyeon Kim, Suwon-si (KR); Jaemin Jung, Suwon-si (KR)

(21) Appl. No.: 19/071,038

(22) Filed: Mar. 5, 2025

(30) Foreign Application Priority Data
Apr. 5, 2024 (KR) 10-2024-0046606

(51) Int. Cl. H10B 43/27; H10B 43/10

(52) U.S. Cl. CPC H10B 43/27; H10B 43/10

(57) ABSTRACT

A vertical memory device includes a first channel on a substrate and extending in a vertical direction substantially perpendicular to an upper surface of a substrate; a first charge storage structure including a first tunnel insulation pattern, a first charge storage pattern, and a first blocking pattern sequentially stacked on an outer sidewall of the first channel in a horizontal direction substantially parallel to the upper surface of the substrate; and first gate electrodes spaced apart from each other in the vertical direction on the substrate and extending around the first charge storage structure, where the first channel includes silicon with a crystal structure in which {100} crystal planes are arranged in the vertical direction.

### CROSS-REFERENCE TO RELATED APPLICATIONS

This application claims priority under 35 USC § 119 to Korean Patent Application No. 10-2024-0046606, filed on Apr. 5, 2024, in the Korean Intellectual Property Office (KIPO), the contents of which are herein incorporated by reference in their entirety.

### TECHNICAL FIELD

The inventive concepts relate to a vertical memory device and a method of manufacturing the same.

### DESCRIPTION OF RELATED ART

Amorphous silicon may be crystallized by a solid-phase crystallization (SPC) process which is typically performed at high temperatures of around 600° C. or more. Metal, such as nickel, may lower the temperature of the SPC process, and this process of using metal to induce crystallization of amorphous silicon at lower temperatures may be referred to as a metal induced crystallization (MIC) process. In the MIC process, changes in covalent bonds may occur at the interface of the metal and amorphous silicon due to free electrons of the metal, and this change in covalent bonds may lower the crystallization temperature of amorphous silicon.

In a method of manufacturing a vertical memory device, channels containing crystallized silicon may be formed by performing the MIC process on a preliminary channel layer containing amorphous silicon. However, current dispersion may occur due to different crystal orientations between the channels.

### SUMMARY

Example embodiments provide a vertical memory device having improved characteristics.

Example embodiments provide a method of manufacturing a vertical memory device having improved characteristics.

According to an aspect of the inventive concept, there is provided a vertical memory device. The vertical memory device may include a first channel, a first charge storage structure and a first gate electrode. The first channel may be on a substrate and may extend in a vertical direction substantially perpendicular to an upper surface of a substrate. The first charge storage structure may include a first tunnel insulation pattern, a first charge storage pattern, and a first blocking pattern sequentially stacked on an outer sidewall of the first channel in a horizontal direction substantially parallel to the upper surface of the substrate. The first gate electrodes may be spaced apart from each other in the vertical direction on the substrate and extending around the first charge storage structure. The first channel may include silicon with a crystal structure in which {100} crystal planes are arranged in the vertical direction.

According to an aspect of the inventive concept, there is provided a vertical memory device. The vertical memory device may include a first memory channel structure and first gate electrodes. The first memory channel structure may be on a substrate and may extend in a first direction substantially perpendicular to an upper surface of the substrate, and a plurality of first memory channel structures may be spaced apart from each other in a second direction and a third direction, the second direction being substantially parallel to the upper surface of the substrate, and the third direction being substantially parallel to the upper surface of the substrate and intersecting the second direction. The first gate electrodes may be spaced apart from each other in the first direction, and may extend around the first memory channel structures. The first memory channel structure may respectively include a first channel on the substrate and extending in the first direction, and a first charge storage structure including a first tunnel insulation pattern, a first charge storage pattern, and a first blocking pattern sequentially stacked on an outer sidewall of the first channel in a horizontal direction substantially parallel to the upper surface of the substrate. A plurality of the first channels respectively included in the first memory channel structures may respectively include silicon with the same crystal orientation.

According to an aspect of the inventive concept, there is provided a vertical memory device. The vertical memory device may include memory channel structures and gate electrodes. The memory channel structures may be on a substrate and may extend in a first direction substantially perpendicular to an upper surface of the substrate, and a plurality of the memory channel structures may be spaced apart from each other in a second direction and a third direction, the second direction being substantially parallel to the upper surface of the substrate, and the third direction being substantially parallel to the upper surface of the substrate and intersecting the second direction. The gate electrodes may be spaced apart from each other in the first direction and may extend around the memory channel structures. The memory channel structure may respectively include a channel on the substrate and extend in the first direction and a charge storage structure including a tunnel insulation pattern, a charge storage pattern, and a blocking pattern sequentially stacked on an outer sidewall of the channel in a horizontal direction substantially parallel to the upper surface of the substrate. The channels may respectively include single crystalline silicon in which {100} crystal planes are arranged in the first direction so that the channels respectively include silicon with the same crystal orientation, and at least one of the channels includes a silicide of a metal.

According to an aspect of the inventive concept, there is provided a method of manufacturing a semiconductor device. In the method, a first insulation layer and a first sacrificial layer may be alternately formed on a substrate to form a mold layer. A channel hole extending through the mold layer and exposing an upper surface of the substrate may be formed. A preliminary channel layer including amorphous silicon in the channel hole may be formed. An aligner including a material that is configured to retard crystallization of silicon on the preliminary channel layer may be formed. A second sacrificial layer including amorphous silicon and a metal layer including metal may be formed sequentially on the aligner. A heat treatment process may be performed to induce a metal induced lateral crystallization (MILC) reaction in the second sacrificial layer and the preliminary channel layer so that the preliminary channel layer is converted into a channel layer responsive to the heat treatment process. The metal layer, the second sacrificial layer, and a portion of the channel layer may be removed to form a channel extending in a vertical direction substantially perpendicular to an upper surface of the substrate. The first sacrificial layer may be replaced with a gate electrode. The channel may include silicon with a crystal structure in which {100} crystal planes are arranged in the vertical direction.

According to an aspect of the inventive concept, there is provided a method of manufacturing a semiconductor device. In the method, a first insulation layer and a first sacrificial layer may be alternately formed on a substrate to form a mold layer. A plurality of channel holes extending in a first direction through the mold layer and exposing an upper surface of the substrate may be formed, and the plurality of channel holes may be spaced apart from each other in a second direction and a third direction, the first direction being substantially perpendicular to the upper surface of the substrate, the second direction being substantially parallel to the upper surface of the substrate, and the third direction being substantially parallel to the upper surface of the substrate and intersecting the second direction. A preliminary channel layer including amorphous silicon in the channel holes may be formed. An aligner including a material that retards crystallization of silicon, a second sacrificial layer including amorphous silicon, and a metal layer including metal may be sequentially formed on the preliminary channel layer. A metal induced lateral crystallization (MILC) process may be performed in the second sacrificial layer and the preliminary channel layer so that the preliminary channel layer is converted into a channel layer responsive to the MILC process. A portion of the channel layer may be removed to form channels in the channel holes, respectively. The first sacrificial layer may be replaced with a gate electrode. The channels may respectively include silicon with the same crystal orientation.

According to an aspect of the inventive concept, there is provided a method of manufacturing a vertical memory device. In the method, a first insulation layer and a first sacrificial layer may be alternately formed on a substrate to form a mold layer. A plurality of channel holes extending in a first direction through the mold layer and exposing an upper surface of the substrate may be formed, and the plurality of channel holes may be spaced apart from each other in a second direction and a third direction, the first direction being substantially perpendicular to the upper surface of the substrate, the second direction being substantially parallel to the upper surface of the substrate, and the third direction being substantially parallel to the upper surface of the substrate and intersecting the second direction. A charge storage layer structure and a preliminary channel layer including amorphous silicon may be formed on sidewalls of the channel holes and the exposed upper surface of the substrate. A filling layer may be formed on the preliminary channel layer and in remaining portions of the channel holes. An aligner including a material that is configured to retard crystallization of silicon, a second sacrificial layer including amorphous silicon, and a metal layer including metal may be sequentially formed on the preliminary channel layer and the filling layer. A heat treatment process may be performed to induce a metal induced lateral crystallization (MILC) reaction in the second sacrificial layer and the preliminary channel layer so that the preliminary channel layer is converted into a channel layer including single crystalline silicon responsive to the heat treatment process. The metal layer may be removed and the second sacrificial layer, the charge storage layer structure and the channel layer may be planarized until an upper surface of the mold layer is exposed to separate the charge storage layer structure and the channel layer into a plurality of charge storage structures and a plurality of channels, respectively. The first sacrificial layer may be replaced with a gate electrode. The channel layer may include silicon with a crystal structure in which {100} crystal planes are arranged in the first direction, and the plurality of channels respectively include silicon having the same crystal orientation.

In methods of manufacturing the vertical memory device in accordance with example embodiments, channels may be formed to include single crystalline silicon with {100} crystal planes arranged along the vertical direction by using an aligner layer.

### BRIEF DESCRIPTION OF THE DRAWINGS

FIGS. 1, 2, and 3 are a plan view and cross-sectional views illustrating a vertical memory device in accordance with example embodiments.

FIGS. 4, 5, 6, 7, 8, 9, 10, 11, 12, 13, 14, 15, 16, 17, 18, 19, 20, and 21 are plan views and cross-sectional views illustrating a method of manufacturing a vertical memory device in accordance with example embodiments.

FIG. 22 is an enlarged cross-sectional view illustrating a vertical memory device in accordance with example embodiments, corresponding or similar to the view of FIG. 3.

FIG. 23 is a cross-sectional view illustrating a vertical memory device in accordance with example embodiments, corresponding or similar to the view of FIG. 2.

FIG. 24 is a cross-sectional view illustrating a vertical memory device in accordance with example embodiments, corresponding or similar to the view of FIG. 2.

FIG. 25 is a cross-sectional view illustrating a vertical memory device in accordance with example embodiments, corresponding or similar to the view of FIG. 2.

FIG. 26 is a cross-sectional view illustrating a method of manufacturing a vertical memory device in accordance with example embodiments.

FIGS. 27 and 28 are a plan view and a cross-sectional view illustrating a vertical memory device in accordance with example embodiments, corresponding or similar to the views of FIGS. 1 and 2, respectively.

FIGS. 29 and 30 are a plan view and a cross-sectional view illustrating a vertical memory device in accordance with example embodiments, corresponding or similar to the views FIGS. 1 and 2, respectively.

### DETAILED DESCRIPTION OF EMBODIMENTS

Hereinafter, a vertical memory device and a method for manufacturing the same in accordance with example embodiments will be described in detail with reference to the accompanying drawings. It will be understood that, although the terms “first,” “second,” and/or “third” may be used herein to describe various elements, these elements should not be limited by these terms. These terms are only used to distinguish one element from another element. The terms “comprises,” “comprising,” “includes” and/or “including,” when used herein, specify the presence of stated elements, but do not preclude the presence of additional elements. The term “and/or” includes any and all combinations of one or more of the associated listed items. The term “connected” may be used herein to refer to a physical and/or electrical connection. When components or layers are referred to herein as “directly” on, or “in direct contact” or “directly connected,” no intervening components or layers are present.

In the specification (and not necessarily in the claims), a vertical direction substantially perpendicular to an upper surface of a substrate may be referred to as a first direction D1, and two directions crossing or intersecting each other among horizontal directions substantially parallel to an upper surface of the substrate may be referred to as second and third directions D2 and D3, respectively. In example embodiments, the second and third directions may be substantially perpendicular to each other.

Each of the first to third directions D1, D2 and D3 may represent not only the direction illustrated in the drawings, but also a reverse or opposite direction to the illustrated direction.

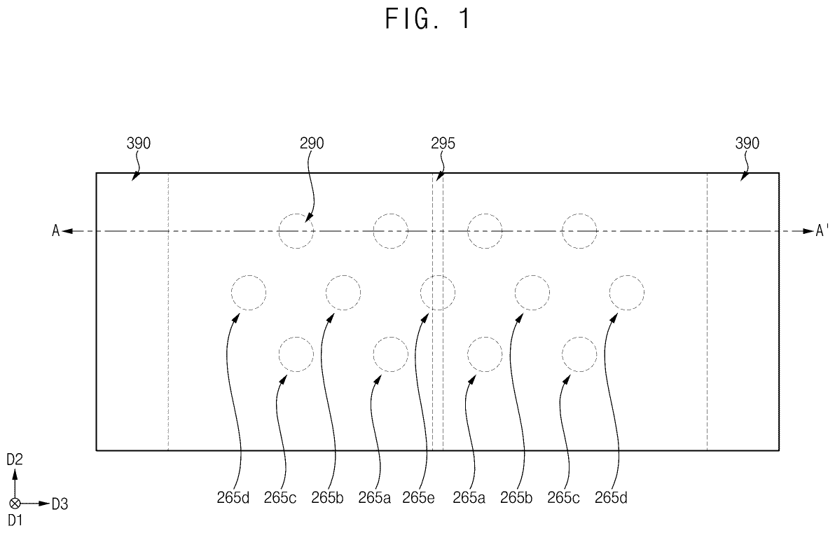

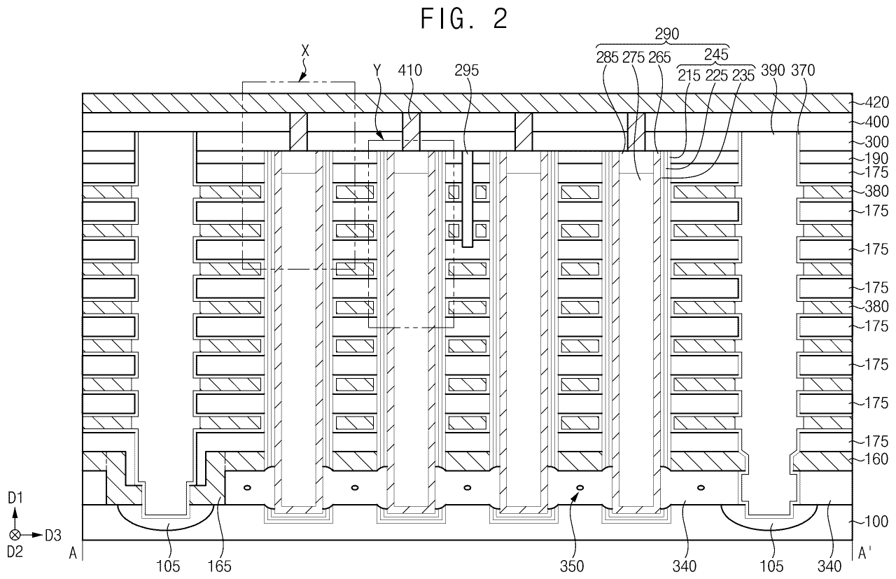

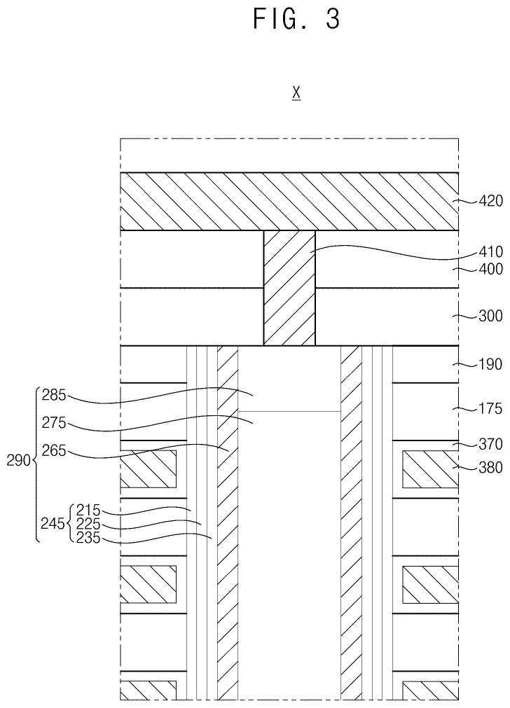

FIGS. 1 to 3 are plan views and cross-sectional views illustrating a vertical memory device in accordance with example embodiments. Particularly, FIG. 1 is the plan view, and FIGS. 2 and 3 are cross-sectional views taken along line A-A′ of FIG. 2. FIG. 3 is an enlarged cross-sectional view of region X of FIG. 2.

Referring to FIGS. 1 to 3, the semiconductor device may include a first memory channel structure 290 and a first gate electrode 380 on a substrate 100.

Additionally, the semiconductor device may include a support layer 160, a support pattern 165, a first insulation pattern 175, a channel connection pattern 340, a second blocking pattern 370, first and second division patterns 295 and 390, a contact plug 451, a bit line 420 and first to third insulating interlayers 190, 300 and 400.

The substrate 100 may include a semiconductor material, e.g., silicon, germanium, silicon-germanium, etc., or a III-V group compound semiconductor, e.g., GaP, GaAs, GaSb, etc. In example embodiments, the substrate 100 may be a silicon-on-insulator (SOI) substrate or a germanium-on-insulator (GOI) substrate.

The first memory channel structure 290 may include a first channel 265, a first charge storage structure 245, a first filling pattern 275 and a first pad 285. In example embodiments, a plurality of first memory channel structures 290 may be spaced apart from each other in the second and third directions D2 and D3 to form a first memory channel structure array.

The first channel 265 may extend in the first direction D1 on the substrate 100 and may have, e.g., a cup or other at least partially hollow shape. In example embodiments, a plurality of first channels 265 may be formed to be spaced apart from each other in the second and third directions D2 and D3 to form a channel array.

The first channel 265 may include single crystalline silicon or quasi-single crystalline silicon. The first channels 265 of the channel array may include silicon crystallized in the same orientation. In other words, each of the first channels 265 of the channel array may include silicon having a crystal structure in which {100} crystal planes are arranged along the first direction D1.

In example embodiments, each of the first channels 265 may partially include, e.g., silicide of a metal. The metal may include, e.g., nickel (Ni), cobalt (Co), palladium (Pd), aluminum (Al), gold (Au), silver (Ag), etc.

The first charge storage structure 245 may be formed on and cover an outer sidewall of the first channel 265. In example embodiments, the first charge storage structure 245 may include an upper portion covering an upper outer sidewall of the first channel 265 and having a cylindrical shape, and a lower portion covering a lower outer sidewall and a lower surface of the first channel 265 and having a cup or at least partially hollow shape. The term “surrounding” or “covering” or “filling” as may be used herein may not require completely surrounding or covering or filling the described elements or layers, but may, for example, refer to partially surrounding or covering or filling the described elements or layers, for example, with one or more discontinuities therein.

Each of the upper and lower portions of the first charge storage structure 245 may include a first tunnel insulation pattern 235, a first charge storage pattern 225 and a first blocking pattern 215 sequentially stacked at the outer sidewall and/or the lower surface of the first channel 265.

The first tunnel insulation pattern 235 and the first blocking pattern 215 may include an oxide, e.g., silicon oxide, and the first charge storage pattern 225 may include nitride, e.g., silicon nitride.

The first filling pattern 275 may occupy most of the space defined by an inner sidewall of the first channel 265, which may have a cup or other at least partially hollow shape. The first filling pattern 275 may include an oxide, e.g., silicon oxide.

The first pad 285 may contact an upper surface of the first filling pattern 275 and fill the space defined by an upper inner sidewall of the first channel 265. The first pad 285 may include polysilicon doped with n-type impurities, a metal, e.g., titanium, tantalum, etc.

In example embodiments, the channel array may include a first channel column 265a comprising a plurality of first channels 265 arranged along the second direction D2, and a second channel column 265b comprising a plurality of first channels 265 arranged along the second direction D2 and respectively spaced, for example, equally from the first channels 265 of the first channel column 265a. The first channels 265 of the first channel column 265a may be oriented in a direction that forms an acute angle with the second direction D2 or the third direction D3 from or relative to the first channels 265 of the second channel column 265b.

The first and second channel columns 265a and 265b may be alternately and repeatedly arranged along the third direction D3. In example embodiments, five of the first channel columns 265a and four of the second channel columns 265b may be arranged alternately along the third direction D3 to form a channel group.

Hereinafter, the channel column at the center may be referred to as a fifth channel column 265e. Four of the channel columns arranged in the third direction D3 from the fifth channel column 265e, following the direction of the arrow, may be referred to as first, second, third and fourth channel columns 265a, 265b, 265c and 265d, respectively. Similarly, four of the channel columns arranged in the third direction D3 opposite to the arrow from the fifth channel column 265e may be referred as first, second, third, and fourth channel columns 265a, 265b, 265c, and 265d, respectively.

Two channel groups arranged in the third direction D3 may collectively form a channel block. Memory cells, each including the first channel 265, the first charge storage structure 245 and the first gate electrode 380 (described later) may also define memory groups and memory blocks that correspond to the channel groups and the channel blocks, respectively. In the semiconductor device, an erase operation may be performed per memory block. In FIG. 1, one memory block is illustrated.

The first gate electrode 380 may surround the first memory channel structures 290, and a plurality of first gate electrodes 380 may be spaced apart from each other along the first direction D1 to form a gate electrode structure.

In example embodiments, each of the first gate electrodes 380 may extend in the second direction D2. The gate electrode structure may have a stepped or staircase shape in which lengths in the second direction decreases in the first direction D1 from a lowermost level toward an uppermost level.

In example embodiments, the first gate electrodes 380 may function as a ground selection line (GSL), a word line and a string selection line (SSL) depending on their positions. The first gate electrodes 380 at the lowermost level may serve as a ground selection line (GSL), the first gate electrodes 380 at the uppermost level and a level therebelow may serve as a string selection line (SSL), and the first gate electrodes 380 at multiple layers between the GSL and the SSL may serve as a word line.

The first gate electrodes 380 that may utilize a gate induced drain leakage (GIDL) phenomenon to serve as a GIDL gate electrode enabling body erase, may additionally be formed at one or multiple levels below the GSL and/or above the SSL, relative to a reference element or layer, such as the substrate 100. Some of the first gate electrodes 380 formed at the multiple layers between the GSL and the SSL may serve as a dummy word line.

Each of the first gate electrodes 380 may include a gate conductive pattern and a gate barrier pattern covering a surface of the gate conductive pattern. The gate conductive pattern may include a metal having a low resistance, e.g., tungsten, titanium, tantalum, platinum, etc., and the gate barrier pattern may include a metal nitride, e.g., titanium nitride, tantalum nitride, etc.

Upper and lower surfaces and a sidewall facing the first channel 265 or the first charge storage structure 245 of each of the first gate electrodes 380 may be covered by the second blocking pattern 370. The second blocking pattern 370 may include a metal oxide e.g., aluminum oxide, hafnium oxide, etc. The second blocking pattern 370 may cover a sidewall of each of the first insulation patterns 175, the support layer 160, the channel connection pattern 340 and sidewalls of the first and second insulating interlayers 190 and 300, and the upper surface of the substrate 100.

The first insulation pattern 175 may be formed between ones of the first gate electrodes 380 adjacent to each other in the first direction D1.

In example embodiments, the first gate electrodes 380 and the first insulation patterns 175 may together form a stack structure. That is, the gate electrode structure comprising the first gate electrodes 380 stacked in the first direction D1, and the first insulation patterns 175 disposed between the first gate electrodes 380 may collectively form the stack structure having a stepped or staircase shape. The first insulation pattern 175 may include an oxide, e.g., silicon oxide.

In example embodiments, the first division pattern 295 may extend through upper portions of ones of the first channels 265, specifically, upper portions of the first channels 265 of the fifth channel column 265e. In addition, the first division pattern 295 may not only extend through the upper portions of the ones of the first channels 265, but also the first insulating interlayer 190, the first gate electrodes 280 at upper two levels, the first insulation patterns 175 at the upper two levels, and a portion of the first insulation pattern 175 at a level below the upper two levels. Accordingly, the first gate electrodes 380 at the upper two levels may be divided in the third direction D3 by the first division pattern 295.

In example embodiments, the stack structure may extend in the second direction D2 and a plurality of stack structures may be spaced apart from each other in the third direction D3. The gate electrode structure within the stack structure may also extend in the second direction D2 and a plurality of gate electrode structures may be spaced apart from each other in the third direction D3. A second division pattern 390 may extend between the stack structures, and thus, the stack structures may be divided in the third direction D3 by second division pattern 390. The second division pattern 390 may include an oxide, e.g., silicon oxide.

The channel connection pattern 340 and the support layer 160 may be sequentially stacked on the substrate 100 in the first direction D1. The channel connection pattern 340 may be formed between the upper and lower portions of the first charge storage structure 245 to contact a lower outer sidewall of each of the first channels 265. Accordingly, the first channels 265 may be electrically connected to each other by the channel connection pattern 340. The channel connection pattern 340 may include, e.g., polysilicon doped with n-type impurities. An air gap 350 may be formed within the channel connection pattern 340.

The support layer 160 may be formed between the channel connection pattern 340 and a lowermost one of the first gate electrode 380, and the support pattern 165 connected thereto may extend through the channel connection pattern 340 to contact the upper surface of the substrate 100. The support pattern 165 may be one of a plurality of support patterns 165, and the support patterns 165 may be formed in various layouts. The support layers 160 and the support pattern 165 may include polysilicon doped with n-type impurities.

The first insulating interlayer 190 may be formed on the substrate 100 to cover the stack structure, the second insulating interlayer 300 may be formed on the first insulating interlayer 190, the first pad 285, the first channel 265, the first charge storage structure 245, the second division pattern 390 and the second blocking pattern 370. The third insulating interlayer 400 may be formed on the second insulating interlayer 300, the second division pattern 390 and the second blocking pattern 370. The first to third insulating interlayers 190, 300 and 400 may include an oxide, e.g., silicon oxide.

The contact plug 410 may extend through the second and third insulating interlayers 300 and 400 to contact an upper surface of the first pad 285. The bit line 420 may extend in the third direction D3 and contact the contact plug 410 therebelow. In example embodiments, a plurality of bit lines 420 may be spaced apart from each other in the second direction D2.

As described above, in the vertical memory device, the first channels 265 of the channel array may all include silicon with the same orientation, that is, silicon in which {100} crystal planes are arranged in the first direction D1. Accordingly, current dispersion may be improved compared to the case in which the first channels 265 include silicon with different orientations from each other. Additionally, since silicon of the first channel 265 may have a crystal structure in which {100} crystal planes with the highest electron mobility are arranged along the first direction D1, electrical characteristics of the vertical memory device may be improved.

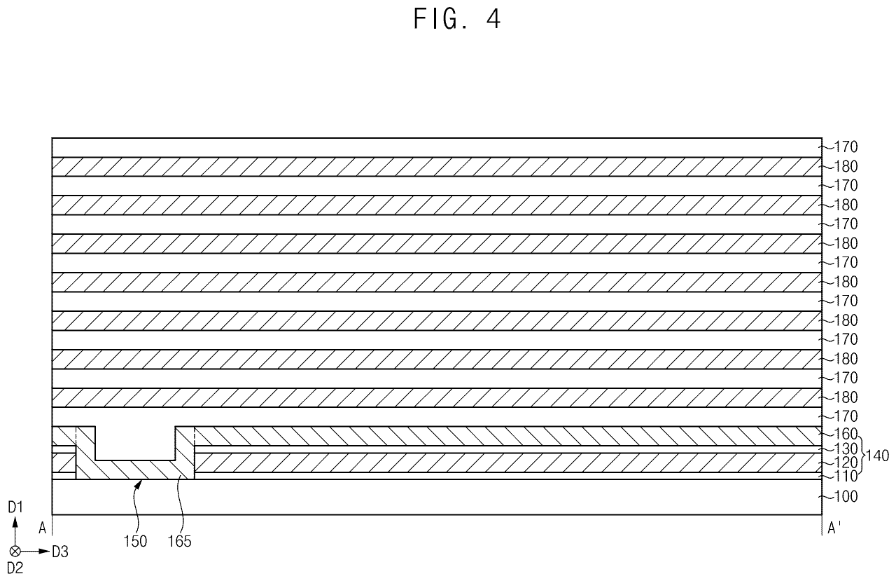

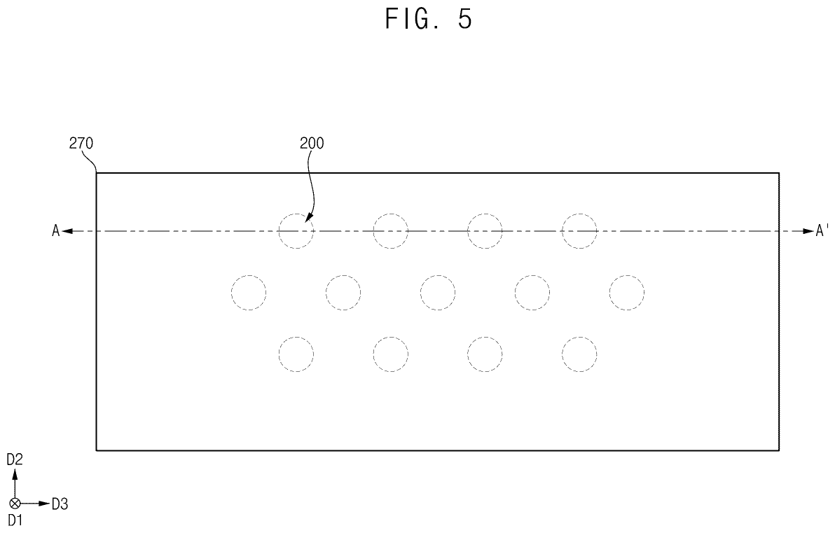

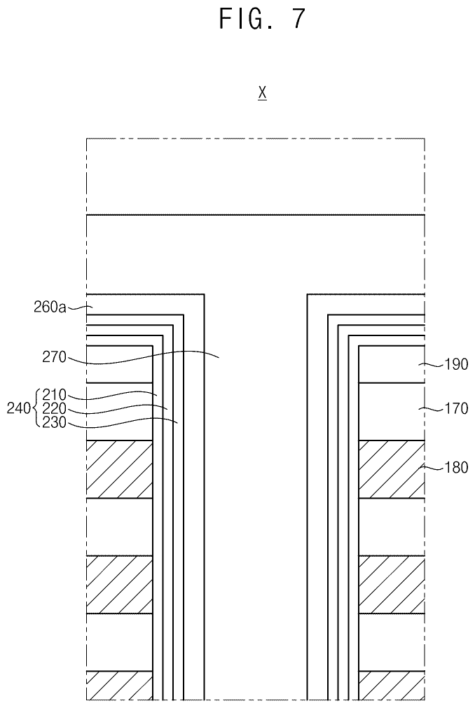

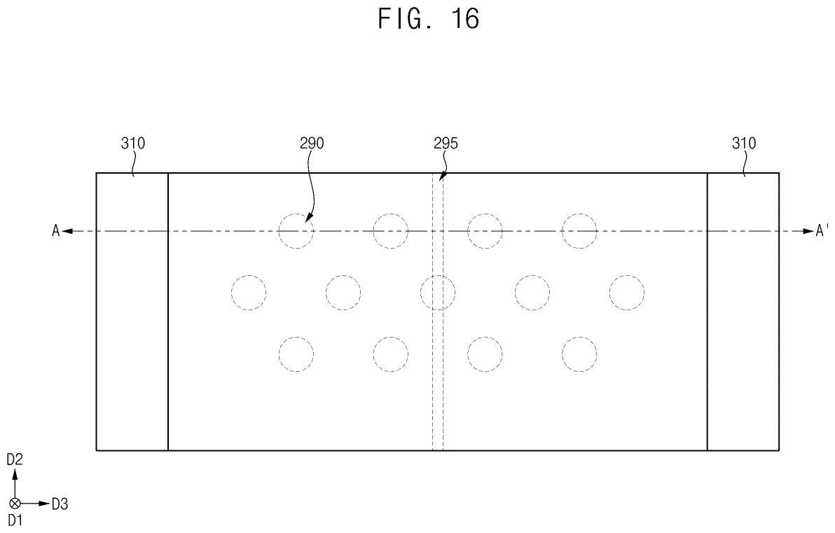

FIGS. 4 to 21 are plan views and cross-sectional views illustrating a method of manufacturing a vertical memory device in accordance with example embodiments. Particularly, FIGS. 5 and 16 are the plan views, and FIGS. 4, 6-15 and 17-21 are the cross-sectional views taken along lines A-A′ of corresponding plan views, respectively. Meanwhile, FIGS. 7-13 and 15 are enlarged cross-sectional view of region X of corresponding cross-sectional views, respectively.

Referring to FIG. 4, a sacrificial layer structure 140 may be formed on the substrate 100, the sacrificial layer structure 140 may be partially removed to form a first opening 150 exposing an upper surface of the substrate 100, and a support layer 160 may be formed on an upper surface of the sacrificial layer structure 140 and the exposed upper surface of the substrate 100. The term “exposed” may be used to describe relationships between elements and/or certain intermediate processes in fabricating a completed semiconductor device, but may not necessarily require exposure of the particular region, layer, structure or other element in the context of the completed device.

The sacrificial layer structure 140 may include first, second and third sacrificial layers 110, 120 and 130 sequentially stacked. Each of the first and third sacrificial layers 110 and 130 may include an oxide, e.g., silicon oxide, and the second sacrificial layer 120 may include a nitride, e.g., silicon nitride.

The support layer 160 may include a material having an etching selectivity with respect to the first to third sacrificial layers 110, 120 and 130, e.g., doped polysilicon or undoped polysilicon. The support layer 160 may have a constant or uniform thickness, and thus a first recess may be formed on a portion of the support layer 160 in the first opening 150. Hereinafter, the portion of the support layer 160 in the first opening 150 may be referred to as a support pattern 165.

An insulation layer 170 may be formed on the support layer 160 to fill the first recess, and an upper portion of the insulation layer 170 may be planarized. The planarization process may be performed by a chemical mechanical polishing (CMP) process and/or an etch back process.

The insulation layers 170 and a fourth sacrificial layer 180 may be alternately and repeatedly formed so as to be stacked on the support layer 160 and the support pattern 165 in the first direction D1, and a mold layer including the insulation layers 170 and the fourth sacrificial layers 180 may be formed. The insulation layer 170 may include an oxide, e.g., silicon oxide, and the fourth sacrificial layer 180 may include a material having an etching selectivity with respect to the insulation layer 170, e.g., a nitride such as silicon nitride.

Thereafter, an etching process for patterning the mold layer using a photoresist pattern as an etching mask and a trimming process for reducing an area of the photoresist pattern may be performed alternately and repeatedly to form mold having a stepped or staircase shape and including a plurality of step layers each of which may include one fourth sacrificial layer 180 and one insulation layer 170 sequentially stacked.

Referring to FIGS. 5 to 7, a first insulating interlayer 190 may be formed on the support layer 160 to cover the mold, and a dry etching process may be performed to form a first channel hole 200 that may extend through the first insulating interlayer 190, the mold, the support layer 160 and the sacrificial layer structure 14 and expose the upper surface of the substrate 100.

In example embodiments, the dry etching process may be performed until the first channel hole 200 exposes the upper surface of the substrate 100, and further, until the first channel hole 200 extends into or through an upper portion of the substrate 100. A plurality of first channel holes 200 may be spaced apart from each other in the second and third directions D2 and D3 to define a channel hole array.

Thereafter, a charge storage layer structure 240 and a preliminary first channel layer 260a may be sequentially formed on a sidewall of the first channel hole 200, the exposed upper surface of the substrate 100 and an upper surface of the first insulating interlayer 190, and a filling layer 270 may be formed on the preliminary first channel layer 260a to fill the first channel hole 200. The preliminary first channel layer 260a may include, e.g., amorphous silicon.

In example embodiments, the preliminary first channel layer 260a may be formed by a chemical vapor deposition (CVD) process, an atomic layer deposition (ALD) process, a physical vapor deposition (PVD) process, etc.

The charge storage layer structure 240 may include a first blocking layer 210, a charge storage layer 220 and a tunnel insulation layer 230 sequentially stacked.

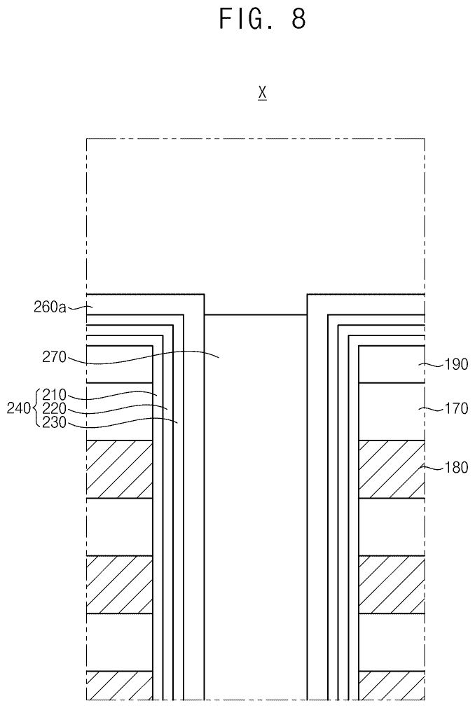

Referring to FIG. 8, an upper portion of the filling layer 270 may be removed by performing, e.g., an etch-back process, and thus, an upper surface and a sidewall of a portion of the preliminary first channel layer 260a on the first insulating interlayer 190 may be exposed.

An upper surface of the filling layer 270 may be lower than the upper surface of the portion of the preliminary first channel layer 260a on the first insulating interlayer 190 relative to a reference layer such as the substrate 100; however, concepts of the present invention is not limited thereto. The upper surface of the filling layer 270 may be substantially coplanar with the upper surface of the preliminary first channel layer 260a, and the sidewall of the portion of the preliminary first channel layer 260a on the first insulating interlayer 190 may not be exposed in some embodiments.

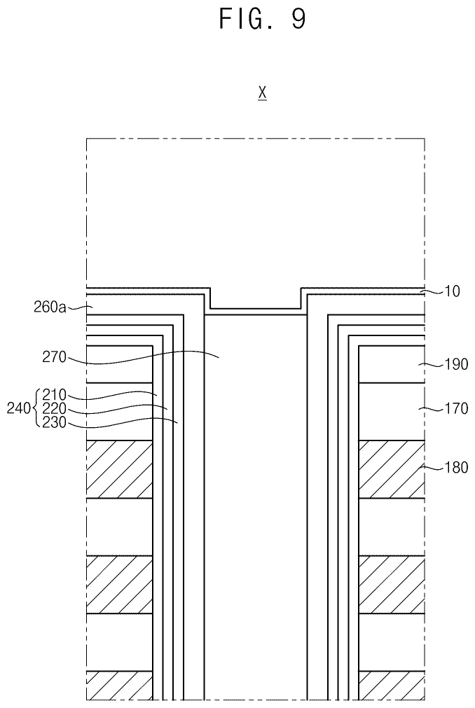

Referring to FIG. 9, an aligner 10 may be formed on the upper surface and the sidewall of the exposed the preliminary first channel layer 260a and the upper surface of the filling layer 270.

The aligner 10 may include a material that retards grain growth. The aligner 10 may include a metal, e.g., titanium (Ti), molybdenum (Mo), tungsten (W), a nitride, e.g., silicon nitride (SiN), a carbide, e.g., silicon carbide (SiC), or a carbonitride, e.g., silicon carbonitride (SiCN).

In example embodiments, the aligner 10 may be formed conformally along the upper surface and the sidewall of the exposed preliminary first channel layer 260a and the upper surface of the filling layer 270. The aligner 10 may be formed to have a thickness of about 0.3nm to 5 nm.

In example embodiments, the aligner 10 may be formed by a chemical vapor deposition (CVD) process, an atomic layer deposition (ALD) process, a physical vapor deposition (PVD) process, etc.

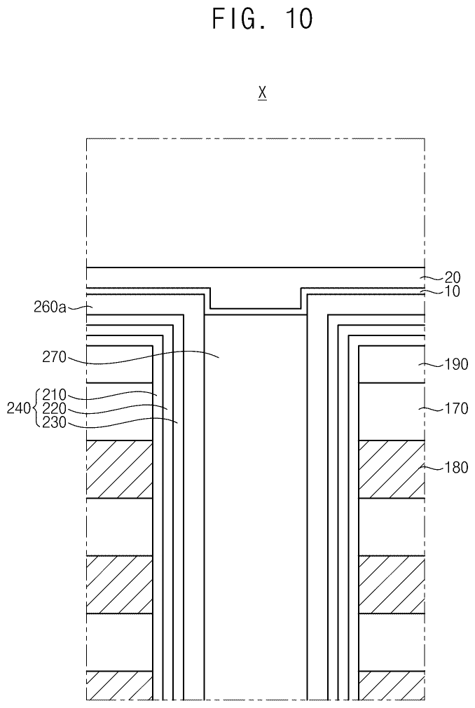

Referring to FIG. 10, a fifth sacrificial layer 20 (which may also be referred to as a first sacrificial layer in some embodiments) may be formed on the aligner 10.

The fifth sacrificial layer 20 may be formed to a sufficient height to cover an upper surface of the aligner 10. The fifth sacrificial layer 20 may include, e.g., amorphous silicon.

In example embodiments, the fifth sacrificial layer 20 may be formed by a chemical vapor deposition (CVD) process, an atomic layer deposition (ALD) process, a physical vapor deposition (PVD) process, etc.

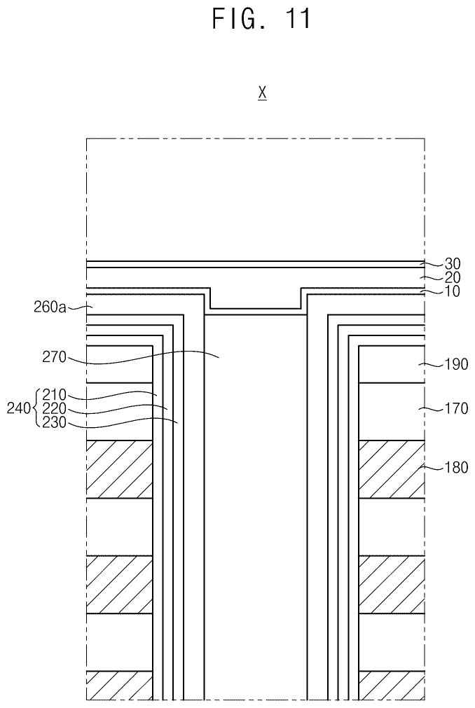

Referring to FIG. 11, a metal layer 30 may be formed on the fifth sacrificial layer 20.

The metal layer 30 may include a metal, e.g., nickel (Ni), cobalt (Co), palladium (Pd), aluminum (Al), gold (Au), silver (Ag), etc.

Amorphous silicon of the fifth sacrificial layer 20 and the metal of the metal layer 30 may react with each other at an interface of the fifth sacrificial layer 20 and the metal layer 30 to form a silicide layer.

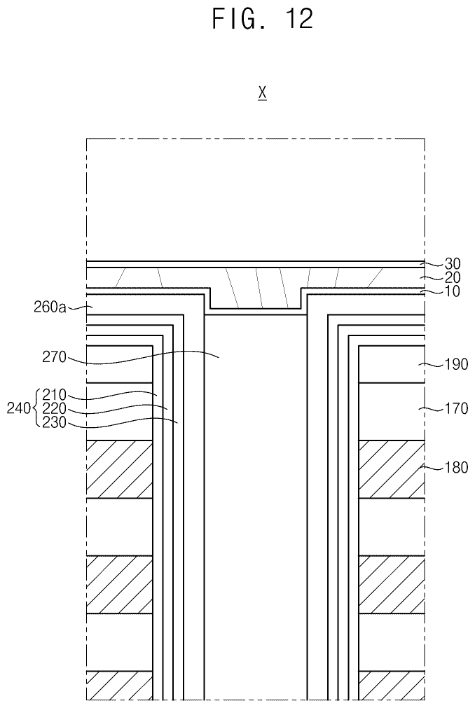

Referring to FIG. 12, a heat treatment process may be performed on the substrate 100, and accordingly, a metal induced lateral crystallization (MILC) reaction may be performed on the fifth sacrificial layer 20.

In example embodiments, the heat treatment process may be performed at about 400° C. to 600° C. for about 0.5 hours to 5 hours.

Specifically, the silicide layer at the interface between the fifth sacrificial layer 20 and the metal layer 30 may diffuse in the first direction D1 into the fifth sacrificial layer 20 containing amorphous silicon. That is, as metal atoms of the silicide layer diffuse into the fifth sacrificial layer 20, voids may be accumulated on the opposite side of the direction of the diffusion, and amorphous silicon of the fifth sacrificial layer 20 may be arranged and crystallized due to the voids. By repeating this process, the entire fifth sacrificial layer 20 may be crystallized.

Crystallization of amorphous silicon may proceed relatively quickly at the {111} crystal planes, and thus, growth in the <111>crystal direction may be predominantly performed. Crystal orientation of silicon grown in the <111>crystal direction may be random, and accordingly, crystal orientation within the fifth sacrificial layer 20 may not be constant.

Crystallization of amorphous silicon may be a driving force of the diffusion of the silicide layer into the fifth sacrificial layer 20. The Gibbs free energy of the crystallization of amorphous silicon has a negative value, so as to be a spontaneous reaction.

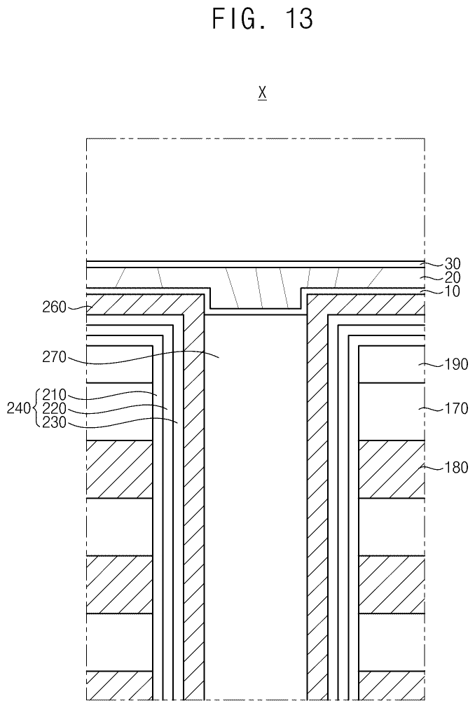

Referring to FIG. 13, the MILC reaction may also be performed on the preliminary first channel layer 260a, and herein, the aligner 10 may interfere and slow down crystallization of the preliminary first channel layer 260a.

Crystallization at the {100} crystal planes, which grows slower than at the {111} crystal planes but has a lower Gibbs free energy, may predominate, and the preliminary first channel layer 260a may be converted into a first channel layer 260 having single crystalline silicon or quasi-single crystalline silicon with the {100} crystal planes uniformly arranged in the first direction D1.

That is, unlike the fifth sacrificial layer 20 where the crystal orientation may not be constant, due to the aligner 10, the first channel layer 260 may include single crystalline silicon with the {100} crystal planes arranged in the first direction D1.

In example embodiments, the metal of the metal layer 30 may partially remain as silicide in the first channel layer 260. That is, at least a portion of the first channel layer 260 may include a silicide of the metal of the metal layer 30.

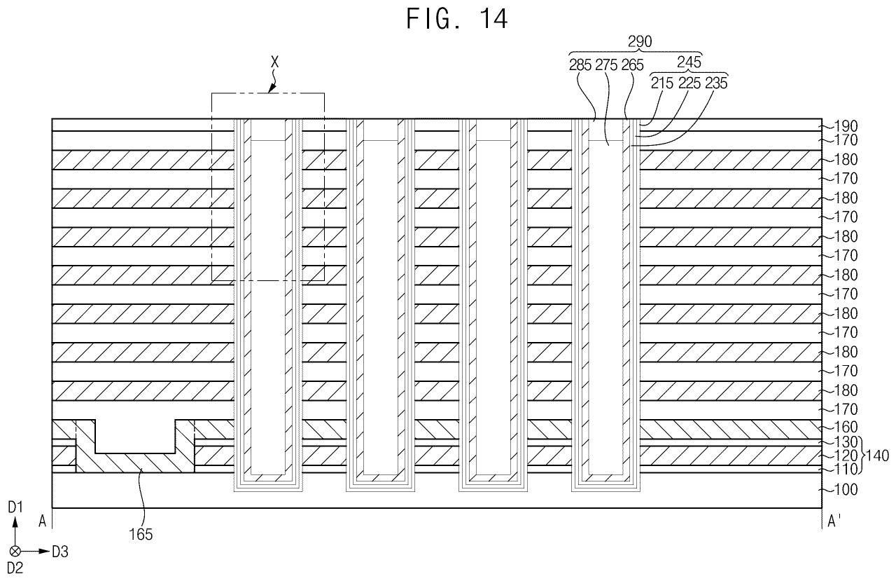

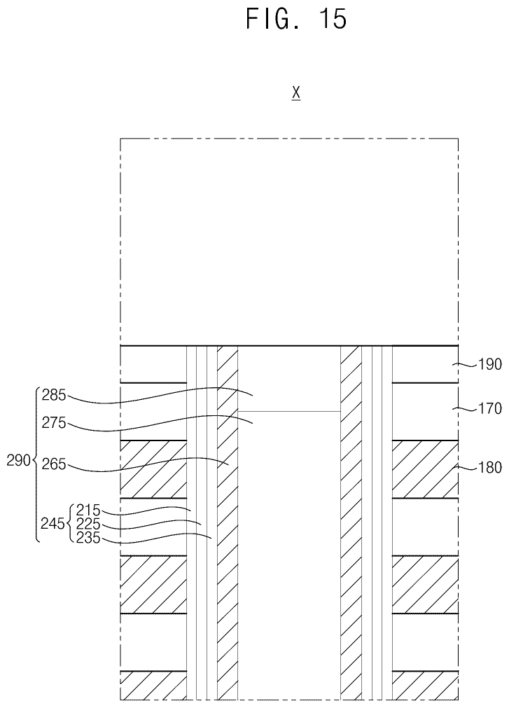

Referring to FIGS. 14 and 15, the metal layer 30 may be removed, and the filling layer 270, the first channel layer 260 and the charge storage layer structure 240 may be planarized until the upper surface of the first insulating interlayer 190 is exposed. Thus, a first filling pattern 275, a first channel 265 and a first charge storage structure 245 may be formed in each of the first channel holes 200.

The first charge storage structure 245 may include a first blocking pattern 215, a first charge storage pattern 225 and a first tunnel insulation pattern 235 sequentially stacked on the sidewall and the bottom of the first channel hole 200.

In example embodiments, the first filling pattern 275 may have a pillar shape extending in the first direction D1, and each of the first channel 265 and the first charge storage structure 245 may have a cup or other at least partially hollow shape.

As the first channel holes 200 in which the first channels 265 are respectively formed define the channel hole array, the first channels 265 in the respective first channel holes 200 may also define a channel array.

Upper portions of the first filling pattern 275 may be removed to form a second recess, a pad layer may be formed on the first filling pattern 275, the first channel 265, the first charge storage structure 245 and the first insulating interlayer 190 to fill the second recess, and the pad layer may be planarized until the upper surface of the first insulating interlayer is exposed to form a first pad 285 contacting an upper inner sidewall of the first channel 265.

The first charge storage structure 245, the first channel 265, the first filling pattern 275 and the first pad 285 may form a first memory channel structure 290. In example embodiments, a plurality of first memory channel structures 290 may be spaced apart from each other in the second and third direction D2 and D3.

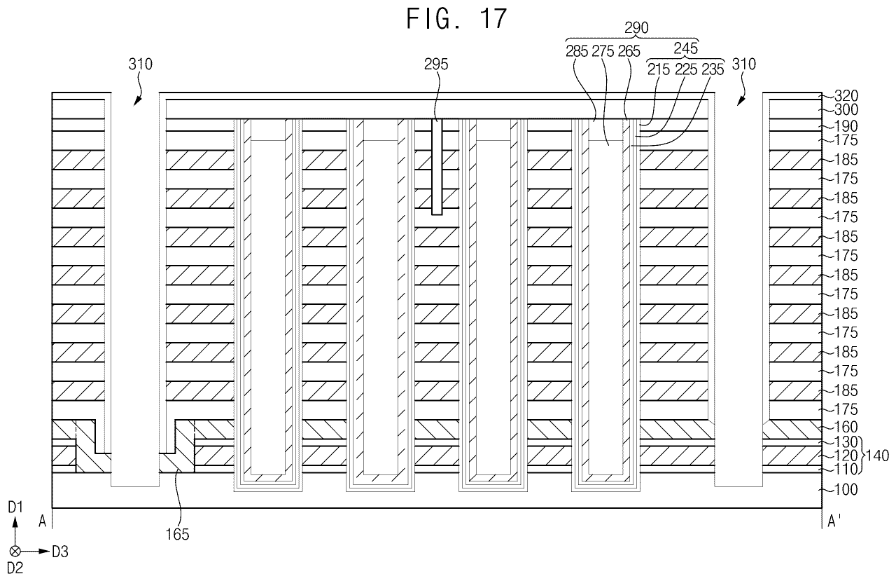

Referring to FIGS. 16 and 17, the first insulating interlayer 190, upper portions of ones of the first memory channel structures 290, ones of the insulation layers 170 and ones of the fourth sacrificial layers 180 may be etched to form a second opening extending in the second direction D2 through the first insulating interlayer 190, the upper portions of ones of the first memory channel structures 290, the ones of the insulation layers 170 and the ones of the fourth sacrificial layers 180, and a first division pattern 295 may be formed in the second opening.

A second insulating interlayer 300 may formed on the first insulating interlayer 190, the first pad 285, the first channel 265, the first charge storage structure 245 and the first division pattern 295. Thereafter, a dry etching process may be performed to form a third opening 310 extending through the first and second insulating interlayers 190 and 300 and the mold.

In example embodiments, the dry etching process may be performed until the third opening 310 exposes an upper surface of the support layer 160 or an upper surface of the support pattern 165, and further performed until the third opening 310 further extends through an upper portion of the support layer 160 or an upper portion of the support pattern 165. As the third opening 310 is formed, the insulation layer 170 and the fourth sacrificial layer 180 of the mold may be exposed.

In example embodiments, the third opening 310 may extend in the second direction D2 and a plurality of third openings 310 may be spaced apart from each other in the third direction D3. As the third opening 310 is formed, the insulation layers 170 and the fourth sacrificial layers 180 included in the mold may be divided into first insulation patterns 175 and fourth sacrificial patterns 185, respectively, each of which may extend in the second direction D2.

A spacer layer may be formed on a sidewall of the third opening 310, the upper surfaces of the support layer 160 and the support pattern 165 exposed by the third opening 310 and the second insulating interlayer 300, and an anisotropic etching process may be performed on the spacer layer to remove a portion of the spacer layer on the upper surfaces of the support layer 160 and the support pattern 165 so that a spacer 320 may be formed. The upper surfaces of the support layer 160 and the support pattern 165 may be partially exposed again. In example embodiments, the spacer 320 may include, e.g., undoped amorphous silicon or undoped polysilicon.

Portions of the support layer 160 and the support pattern 165 uncovered by the spacer 320 and the sacrificial layer structure 140 therebelow may be removed to enlarge the third opening 310 downwards, i.e., towards the substrate 100. Accordingly, the third opening 310 may expose the upper surface of the substrate 100, and further, extend through the upper portion of the substrate 100.

While the sacrificial layer structure 140 is partially removed, the sidewall of the third opening 310 may be covered by the spacer 320 which includes a different material from the sacrificial structure 140. Accordingly, the first insulation patterns 175 and the fourth sacrificial patterns 185 may not be removed.

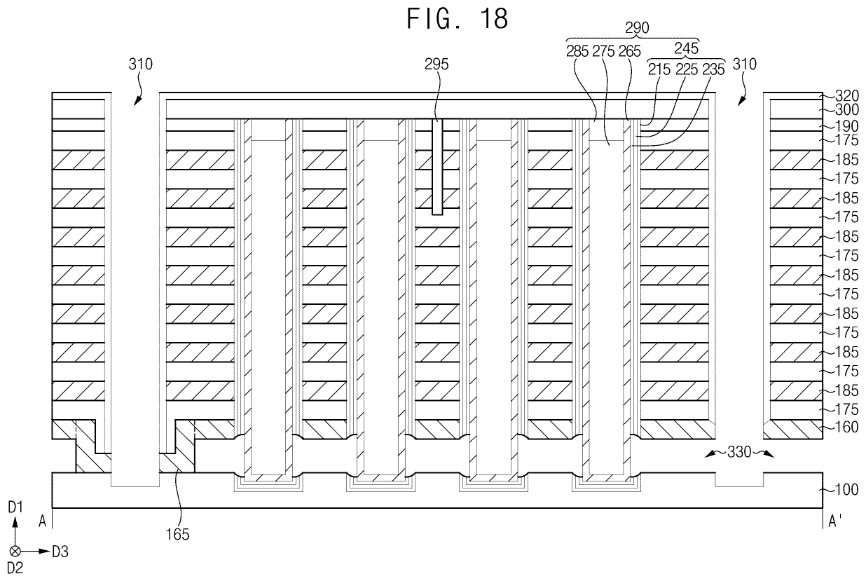

Referring to FIG. 18, the sacrificial layer structure 140 may be removed through the third opening 310 by, e.g., a wet etching process to form a first gap 330 exposing a lower outer sidewall of the first charge storage structure 245. The wet etching process may be further performed to remove the exposed portion of the first charge storage structure 245 so that a lower outer sidewall of the first channel 265 may be exposed.

The wet etching process may be performed using, e.g., hydrofluoric acid (HF) and/or phosphoric acid (H₃PO₄). The support layer 160, the support pattern 165, the first channel 265 and the first filling pattern 275 may support the mold during the formation of the first gap, preventing the mold from collapsing.

As the first gap 330 is formed, the first charge storage structure 245 may be divided into an upper portion extending through the mold and covering most of an outer sidewall of the first channel 265, and a lower portion covering a lower surface of the first channel 265 and extending into or through the upper portion of the substrate 100.

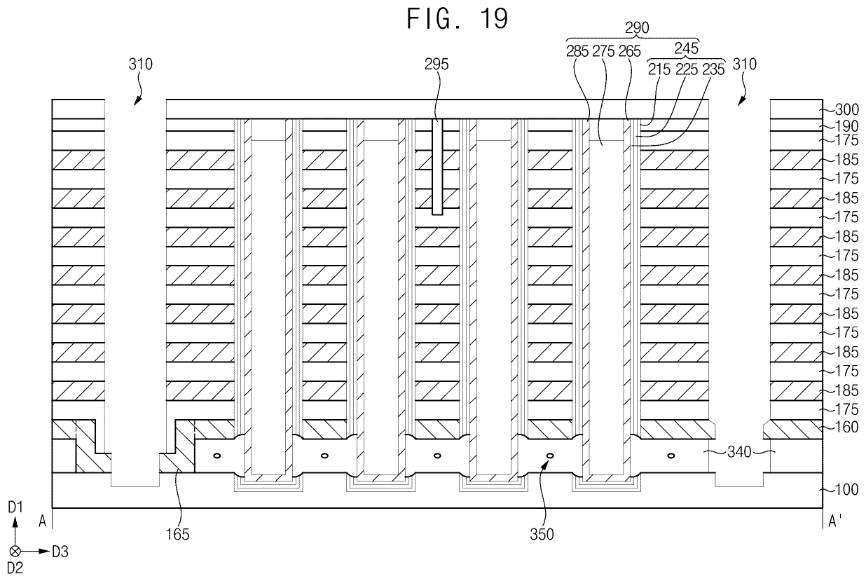

Referring to FIG. 19, the spacer 320 may be removed, and a channel connection pattern 340 may be formed to fill the first gap 330.

The channel connection pattern 340 may be formed by forming a channel connection layer on the substrate 100 and the second insulating interlayer 300 to fill the third opening 310 and the first gap 330, and removing a portion of the channel connection layer in the third opening 310 by, e.g., an etch back process. The channel connection layer may include, e.g., polysilicon doped with n-type impurities. As the channel connection pattern 340 is formed, the first channels 265 between neighboring ones of the third opening 310 in the third direction D3 may be connected with each other.

An air gap 350 may be formed in the channel connection pattern 340.

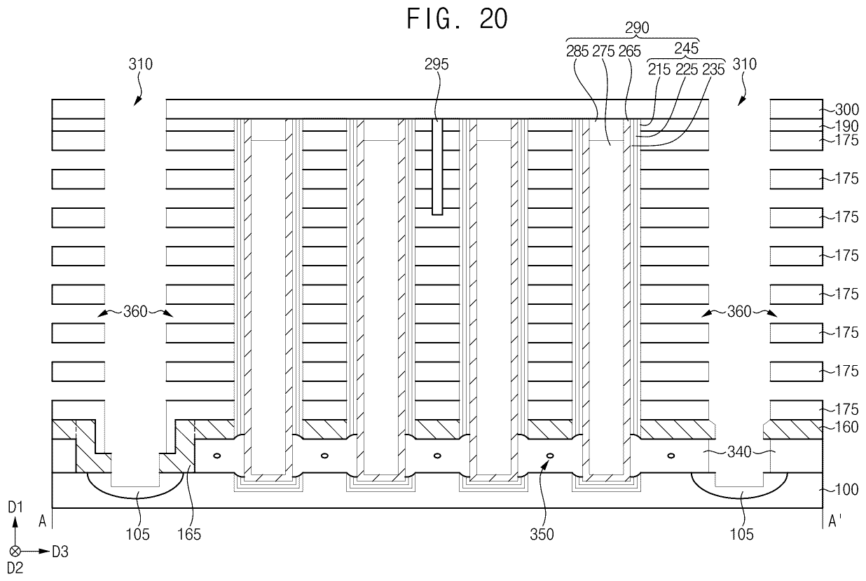

Referring to FIG. 20, the upper portion of the substrate 100 exposed by the third opening 310 may be doped with, for example, n-type impurities to form an impurity region 105.

The fourth sacrificial patterns 185 exposed by the third opening 310 may be removed to form a second gap 360 between neighboring ones of the first insulation patterns 175 in the first direction D1, and outer sidewalls of the first charge storage structure 245 and the first division pattern 295 may be exposed by the second gap 360. In example embodiments, a wet etching process may be performed using, e.g., phosphoric acid (H₃PO₄) or sulfuric acid (H₂SO₄) to remove the fourth sacrificial patterns 185.

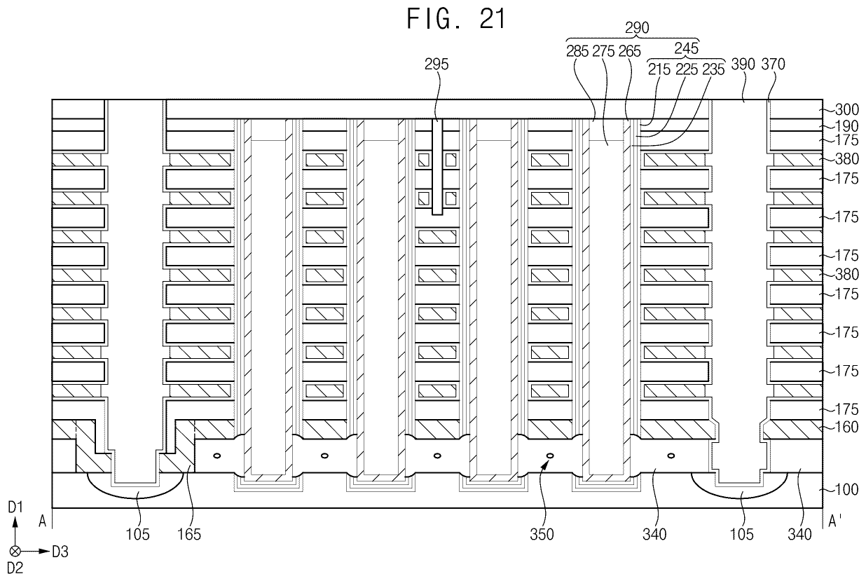

Referring to FIG. 21, a second blocking layer may be formed on the outer sidewalls of the first charge storage structure 245 and the first division patterns 295 exposed by the second gap 260, inner walls of the second gaps 360, surfaces of the first insulation patterns 175, the sidewall of the support layer 160, the sidewall of the support pattern 165, a sidewall of the channel connection pattern 340, the upper surface of the substrate 100 and the upper surface of the second insulating interlayer 300, and a gate electrode layer may be formed on the second blocking layer. The gate electrode layer may include a gate barrier layer and a gate conductive layer sequentially stacked.

The gate electrode layer may be partially removed to form a first gate electrode 380 in each of the second gaps 360. In example embodiments, the gate electrode layer may be partially removed by a wet etching process.

In example embodiments, the first gate electrode 380 may extend in the second direction D2, and a plurality of first gate electrodes 380 may be spaced apart from each other in the first direction D1 to form a gate electrode structure. In example embodiments, a plurality of gate electrode structures may be spaced apart from each other by the third openings 310 in the third direction D3.

A division layer may be formed on the second blocking layer to fill the third opening 310, and may be planarized until the upper surface of the second insulating interlayer 300 is exposed. Accordingly, the second blocking layer may be transformed to a second blocking pattern 370, and the division layer may be transformed to a second division pattern 390 filling the third opening 310 and extending in the second direction D2.

Referring to FIGS. 1 to 3 again, the third insulating interlayer 400 may be formed on the second insulating interlayer 300, the second division pattern 390 and the second blocking pattern 370, and the contact plug 410 may be formed to extend through the second and third insulating interlayers 300 and 400 to contact an upper surface of the first pad 285.

A bit line 420 may be formed to contact an upper surface of the contact plug 410. In example embodiments, the bit line 420 may extend in the third direction D3 and a plurality of bit lines 420 may be spaced apart from each other in the second direction D2.

Upper contact plugs that contact upper surfaces of the first gate electrodes 380 and upper wirings that apply electrical signals to the upper contact plugs may be additionally formed, and manufacturing of the vertical memory device may be completed.

As described above, crystallization of amorphous silicon may dominantly occur at the {111} crystal planes during the MILC process on amorphous silicon. The silicon crystal orientation of silicon growth in the <111>crystal direction may be random. Therefore, during the MILC process to crystallize the preliminary first channel layer 260a containing amorphous silicon, even if the silicon crystal orientation becomes constant within each of the first channels 260, the first channels 260 may exhibit different orientations from each other.

However, in the method of manufacturing a vertical memory device according to example embodiments, the aligner 10, the fifth sacrificial layer 20 and the metal layer 30 may be sequentially formed on the preliminary first channel layer 260a, and the MILC process may be performed to crystalize silicon of the fifth sacrificial layer 20 and the preliminary first channel layer 260a. While silicon growth in the <111>crystal direction may be dominant within the fifth sacrificial layer 20 so that silicon of the fifth sacrificial layer 20 is formed to include crystals with different orientations, due the aligner 10, silicon growth in the <100>crystal direction may be dominantly performed within the preliminary first channel layer 260a, and the first channel layer 260 may be formed to include silicon having a crystal structure where {100} crystal planes are arranged in the first direction D1. Accordingly, the first channels 265 may all be formed to include silicon of the same orientation, and current dispersion between the first channels 265 may be improved.

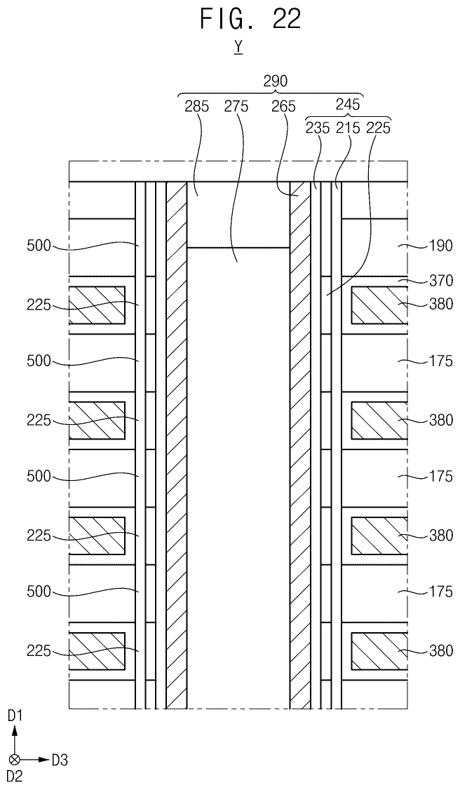

FIG. 22 is an enlarged cross-sectional view illustrating a vertical memory device in accordance with example embodiments, corresponding to FIG. 3.

The vertical memory device may be substantially the same as or similar to a vertical memory of FIGS. 1 to 3, except for the first charge storage pattern 225, and thus repeated explanations are omitted herein.

Referring to FIG. 22, a plurality of the first charge storage patterns 225 may be spaced apart from each other in the first direction D1.

In example embodiments, the first charge storage patterns 225 may respectively face the first gate electrodes 380 in a horizontal direction (e.g., D2, D3, and a second insulation pattern 500 may be formed between neighboring ones of the first charge storage patterns 225 in the first direction D1. The second insulation pattern 500 may include an oxide, e.g., silicon oxide.

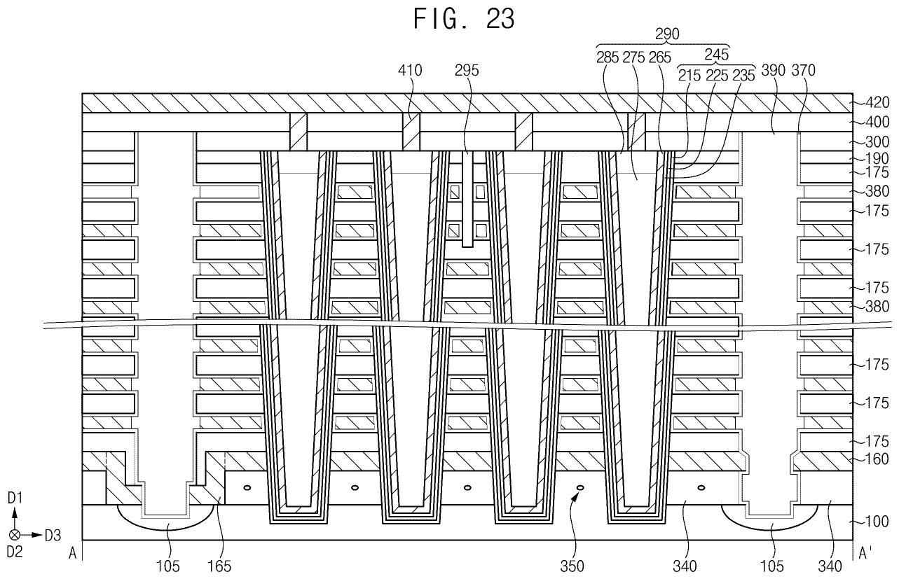

FIG. 23 is a cross-sectional view illustrating a vertical memory device in accordance with example embodiments, corresponding to FIG. 2.

The vertical memory device may be substantially the same as or similar to a vertical memory of FIGS. 1 to 3, except for the shape of the first memory channel structure 290, and thus repeated explanations are omitted herein.

Referring to FIG. 23, the first memory channel structure 290 may include lower and upper portions sequentially stacked in the first direction D1, and each of the lower and upper portions may have a width that is tapered or gradually decreasing from a top toward a bottom thereof (e.g., toward the substrate 100). In example embodiments, an upper surface of the lower portion of the first memory channel structure 290 may have a width greater than a lower surface of the upper portion of the first memory channel structure 290.

FIG. 23 shows that the first memory channel structure 290 includes two portions stacked in the first direction D1, however, the inventive concept may not be limited thereto, and may include more than two portions stacked in the first direction D1. Each of the portions of the first memory channel structure 290 may have a width gradually decreasing from a top toward a bottom thereof, and an upper surface of a portion of the first memory channel structure 290 may have a width greater than a lower surface of a portion of the first memory channel structure 290 thereon.

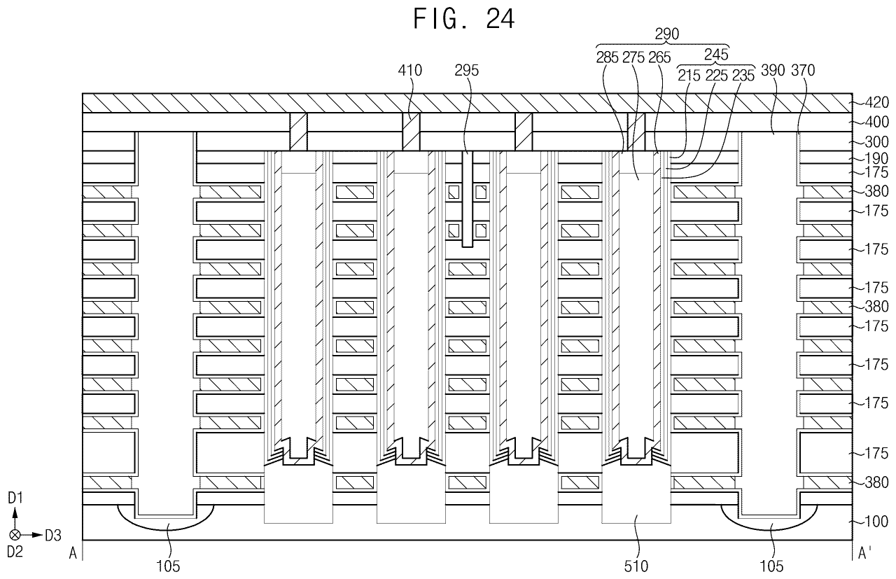

FIG. 24 is a cross-sectional view illustrating a vertical memory device in accordance with example embodiments, corresponding to FIG. 2.

The vertical memory device may be substantially the same as or similar to a vertical memory of FIGS. 1 to 3, except for the first memory channel structure 290, the channel connection pattern 340, the support layer 160 and the support pattern 165, and thus repeated explanations are omitted herein.

Referring to FIG. 24, the first memory channel structure 290 may further include a semiconductor pattern 510 on the substrate 100, and the first charge storage structure 245, the first channel 265, the first filling pattern 275 and the first pad 285 may be formed on the semiconductor pattern 510.

The semiconductor pattern 510 may include, for example, single crystalline silicon or polysilicon. In an example embodiment, an upper surface of the semiconductor pattern 510 may be located between lower and upper surfaces of the first insulation pattern 175 that is between the first gate electrodes 380 respectively formed at the lower two levels, i.e., the lowermost first insulation pattern 175 on the substrate 100.

The first charge storage structure 245 may have a cup or other at least partially hollow shape with an opening in a center of a bottom thereof and may contact an edge portion of the upper surface of the semiconductor pattern 510. The first channel 265 may have a cup or other at least partially hollow shape and may contact a center portion of the upper surface of the semiconductor pattern 510. Accordingly, the first channel 265 may be electrically connected to the substrate 100 through the semiconductor pattern 510.

The channel connection pattern 340, the support layer 160 and the support pattern 165 may not be formed between the substrate 100 and the first gate electrode 380 at the lowermost level. In an example embodiment, the lowermost first insulation pattern 175 disposed between the first gate electrodes 380 respectively formed at the lower two levels may be thicker than the first insulation patterns 175 at upper levels.

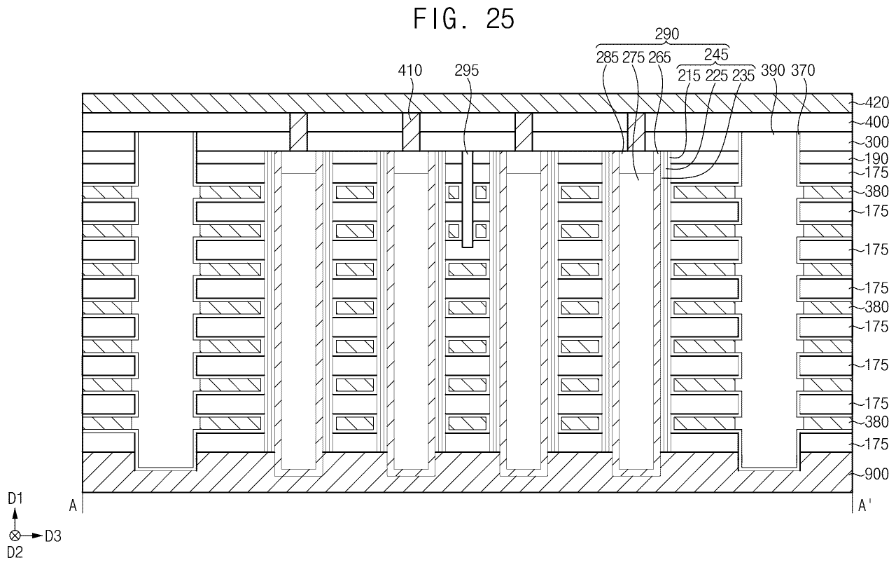

FIG. 25 is a cross-sectional view illustrating a vertical memory device in accordance with example embodiments, corresponding to FIG. 2.

The vertical memory device may be substantially the same as or similar to a vertical memory of FIGS. 1 to 3, except for the first memory channel structure 290, the channel connection pattern 340, the support layer 160, the support pattern 165 and the common source plate (CSP) 900, and thus, repeated explanations are omitted herein.

Referring to FIG. 25, the semiconductor device may not include the channel connection pattern 340, the support layer 160 and the support pattern 165, and may include the CSP 900 instead of the substrate 100.

The CSP 900 may include, for example, polysilicon doped with n-type impurities. Alternatively, the CSP 900 may include a metal silicide layer and a polysilicon layer doped with n-type impurities sequentially stacked. The metal silicide layer may include, for example, tungsten silicide.

The first memory channel structure 290 may be formed on the CSP 900. The first memory channel structure 290 may extend through the first insulating interlayer 190 and the stack structure to contact the CSP 900.

The first charge storage structure 245 may cover the upper outer sidewall of the first channel 265. In example embodiments, the first charge storage structure 245 may cover the upper outer sidewall of the first channel 265 to have a cylindrical shape. The first charge storage structures 245 may not be formed on the lower outer sidewalls of the first channels 265, and the CSP 900 may contact the lower outer sidewall of the first channels 265 to electrically connect the first channels 265 to each other. That is, the first memory channel structures 290 may be electrically connected to each other by the CSP 900.

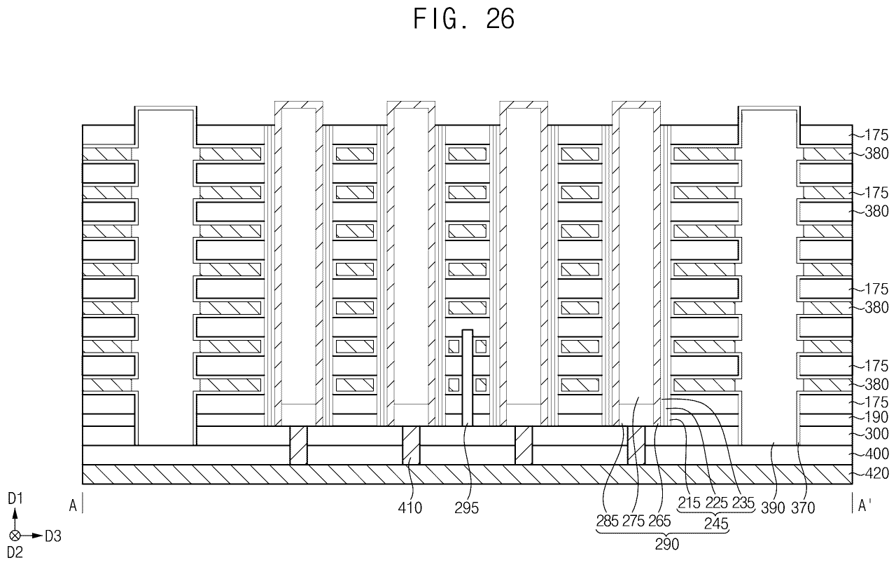

FIG. 26 is a cross-sectional view illustrating a method of forming a vertical memory device in accordance with example embodiments. Specifically, FIG. 26 is a cross-sectional view taken along line A-A′ of a corresponding plan view. This method may include processes substantially the same as or similar to those illustrated with reference to FIGS. 1 to 21, and thus repeated explanations thereof are omitted herein.

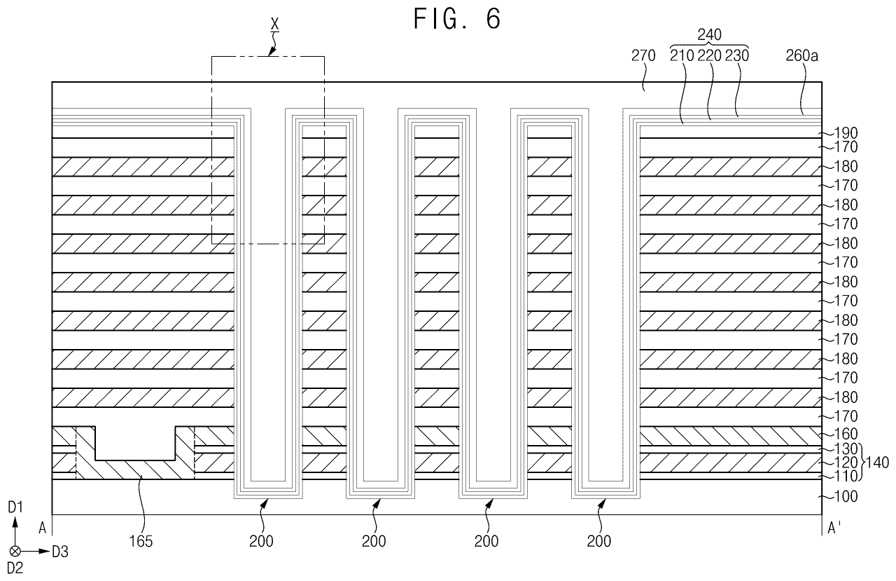

Referring to FIG. 26, processes substantially the same as or similar to those illustrated with reference to FIGS. 4 and 21 and FIGS. 1 to 3 may be performed. However, unlike the processes illustrated with reference to FIGS. 5 and 6, the sacrificial layer structure 140, the support layer 160 and the support pattern 165 may not be formed, and unlike the processes illustrated with reference to FIGS. 18 and 19 the channel connection pattern 340 may not be formed.

The substrate 100 and various structures formed on the substrate 100 may be turned over. Hereinafter, the following description may be based on a state in which top and bottom of the substrate 100 and the various structure thereon are inverted. It will be understood that spatially relative terms such as ‘on,’ ‘upper,’ ‘upper portion,’ ‘upper surface,’ ‘below,’ ‘lower,’ ‘lower portion,’ ‘lower surface,’ ‘side surface,’ and the like may be denoted by reference numerals and refer to the drawings, except where otherwise indicated. Such spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations), and the spatially relative descriptors used herein may be interpreted accordingly.

The substrate 100 may be removed through, for example, a grinding process and/or an etching process. Accordingly, an upper portion of the first charge storage structure 245 and an upper surface of an uppermost one of the first insulation patterns 175 may be exposed.

The exposed upper portion of the first charge storage structure 245 may be removed. Accordingly, an upper outer sidewall and an upper surface of the first channel 265 may be exposed.

A CSP 900 may be formed on the upper outer sidewall and the upper surface of the first channel 265 and the upper surface of the uppermost one of the first insulation patterns 175, and the manufacturing the semiconductor device may be completed. The CSP 900 may contact the upper outer sidewalls and the upper surfaces of the first channels 265 to electrically connect the first channels 265 to each other, and thus, the first memory channel structures 290 may be electrically connected to each other by the CSP 900, as shown in FIG. 25.

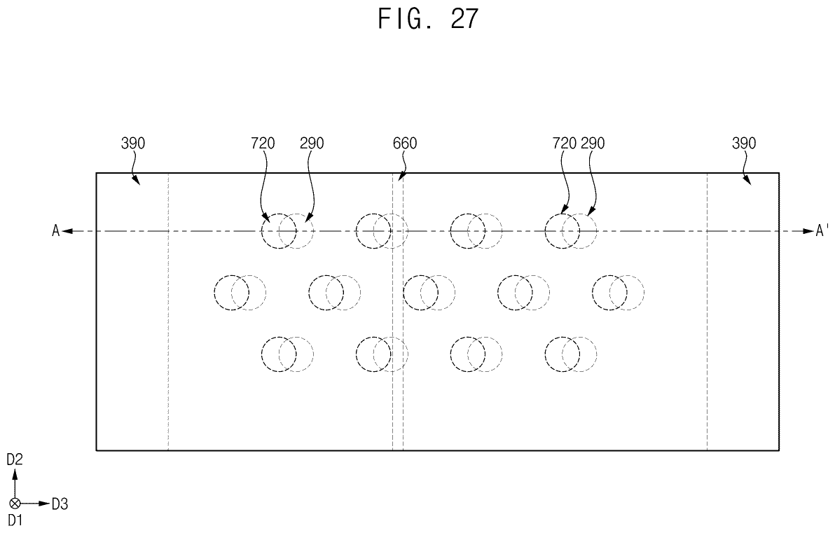

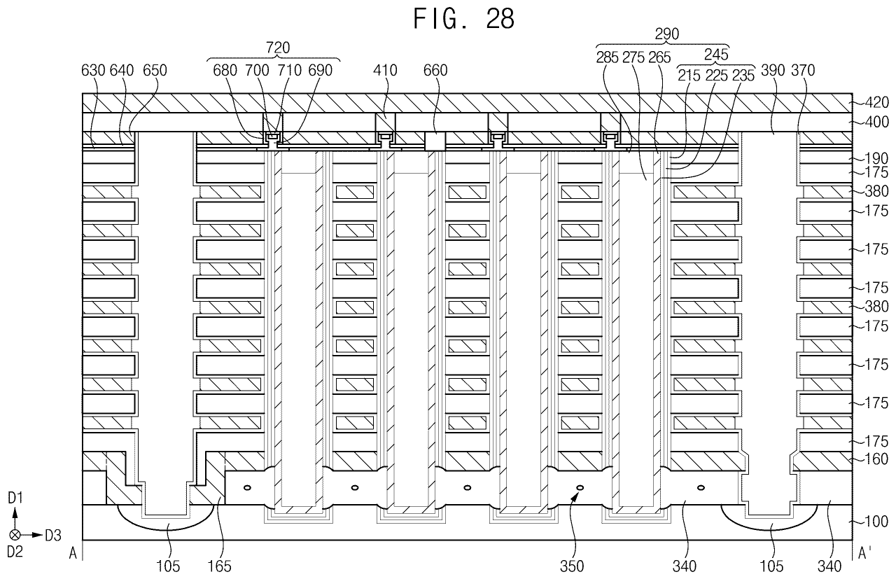

FIGS. 27 and 28 are cross-sectional views illustrating a vertical memory device in accordance with example embodiments, corresponding to FIGS. 1 and 2, respectively.

The vertical memory device may be substantially the same as or similar to a vertical memory of FIGS. 1 to 3, except for further including a fourth insulating interlayer 630, an etch stop layer 640, a second gate electrode 650 and a second memory channel structure 720, and thus, repeated explanations are omitted herein.

Referring to FIGS. 27 and 28, the fourth insulating interlayer 630 and the etch stop layer 640 may be sequentially stacked in the first direction D1 on the first insulating interlayer 190.

The fourth insulating interlayer 630 may include an insulating nitride, e.g., silicon nitride, and the etch stop layer 640 may include an oxide, e.g., silicon oxide.

The second gate electrode 650 may be formed on the etch stop layer 640. The second gate electrode 650 may form the gate electrode structure together with the first gate electrodes 380 therebelow. The second gate electrode 650 may include, e.g., polysilicon doped with impurities.

In an example embodiment, the first gate electrode 380 at the lowermost level may serve as the GSL, the second gate electrode 650 may serve as the SSL, and the first gate electrodes 380 stacked at respective levels between the GSL and the SSL may serve as the word lines.

In example embodiments, the third division pattern 660 may extend in the second direction D2, and may be disposed between ones of the second division patterns 390 adjacent to each other in the third direction D3. Accordingly, the second gate electrode 650 may be divided in the third direction D3.

The second memory channel structure 720 may include a second filling pattern 700, a second channel 690, a second charge storage structure 680 and a second pad 710 corresponding to the first memory channel structure 290. In example embodiments, the second memory channel structure 720 may extend through the fourth insulating interlayer 630, the etch stop layer 640 and the second gate electrode 650 to at least partially contact an upper surface of the first memory channel structure 290.

In example embodiments, the second channel 690 may include a lower portion that may extend through the fourth insulating interlayer 630 and have a first width, a central portion that may extend through the etch stop layer 640 and have a second width, and an upper portion that extends through a portion of the second gate electrode 650 and have a third width. Each of the first and third widths may be greater than the second width. The upper portion of the second channel 690 may have a cup or partially hollow shape, and the second filling pattern 700 may fill the space defined by the upper portion of the second channel 690.

The second charge storage structure 680 may extend through the second gate electrode 650 and cover a sidewall and an edge portion of a lower surface of the upper portion of the second channel 690 and a sidewall of the second pad 710. The second charge storage structure 680 may include a second tunnel insulation pattern, a second charge storage pattern and a third blocking pattern sequentially stacked in the horizontal direction at the outer sidewall of the second channel 690, corresponding to the first charge storage structure 245.

The second pad 710 may contact an inner sidewall of the second charge storage structure 680 while contacting upper surfaces of the second filling pattern 700 and the second channel 690.

In example embodiments, a plurality of second memory channel structures 720 may be formed to respectively contact the first memory channel structures 290, and thus, the second memory channel structures 720 may be spaced apart from each other in the second and third directions D2 and D2 to form a second memory channel structure array.

The second channel 690 may include, e.g., undoped polysilicon, the second filling pattern 700 may include an oxide, e.g., silicon oxide, and the second pad 710 may include, e.g., polysilicon doped with impurities.

The second tunnel insulation pattern may include an oxide, e.g., silicon oxide, the second charge storage pattern may include a nitride, e.g., silicon nitride, and the third blocking pattern may include an oxide, e.g., silicon oxide.

The fourth insulating interlayer 630, the etch stop layer 640, the second gate electrode 650 and the second memory channel structure 720 may be formed by performing the following processes.

The processes illustrated with reference to FIGS. 4 to 15 may be performed, however, the first division pattern 295 may not be formed. The fourth insulating interlayer 630, the etch stop layer 640 and the second gate electrode layer may be sequentially stacked on the first insulating interlayer 190.

A fourth opening may be formed to extend through the second gate electrode layer and the etch stop layer 640 to expose an upper surface of the fourth insulating interlayer 630, and a third division pattern 660 may be formed within the fourth opening. As the third division pattern 660 is formed, the second gate electrode layer may be divided into a plurality of second gate electrodes 650 each extending in the second direction D2. The second gate electrode 650 may form the gate electrode structure together with the first gate electrode 380 therebelow.

A second channel hole may be formed to extend through the second gate electrode 650 and expose an upper surface of the etch stop layer 640. In example embodiments, a plurality of second channel holes may be formed to be spaced apart from each other in the second and third directions D2 and D3 to respectively partially overlap the first memory channel structures 290 in the first direction D1.

A second charge storage layer structure may be formed on a sidewall and a bottom of the second channel hole, the second gate electrode 650 and the third division pattern 660, and an etch-back process may be performed on the second charge storage layer structure to form the second charge storage structure 680 on the sidewall and an edge portion of the bottom of the second channel hole.

A portion of the etch stop layer 640 exposed by the second charge storage structure 680 and a portion of the fourth insulating interlayer 630 therebelow may be removed to enlarge the second channel hole in the first direction D1, and a portion of the fourth insulating interlayer 630 may be additionally removed to enlarge the second channel hole in the horizontal direction. Accordingly, at least a portion of the upper surface of the first memory channel structure 290 may be exposed. The second channel hole may also expose a portion of the first insulating interlayer 190 adjacent to the first memory channel structure 290.

The second channel 690, the second filling pattern 700 and the second pad 710 may be formed within the second channel hole. The second charge storage structure 680, the second channel 690, the second filling pattern 700 and the second pad 710 may collectively form the second memory channel structure 720. The second memory channel structure 720 may contact the upper surface of the first memory channel structure 290 and be electrically connected to the first memory channel structure 290.

The processes illustrated with reference to FIGS. 16 to 21 may be performed, and manufacturing of the vertical memory device may be completed.

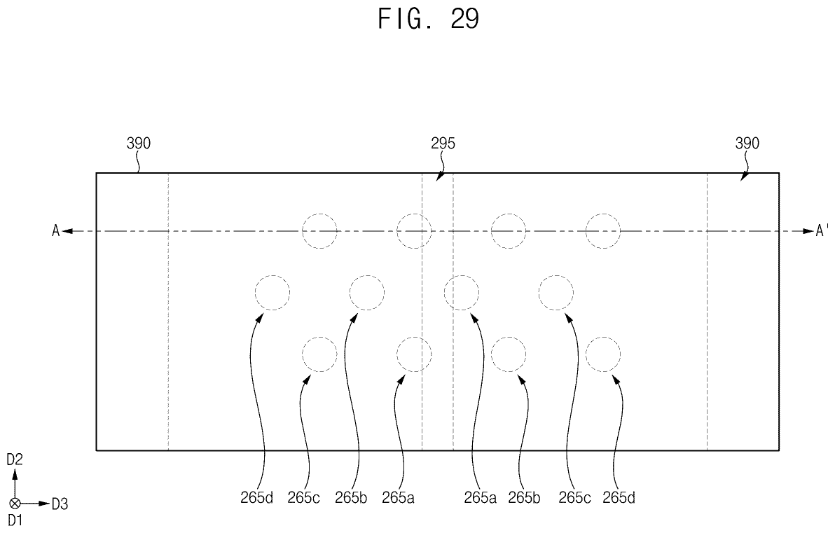

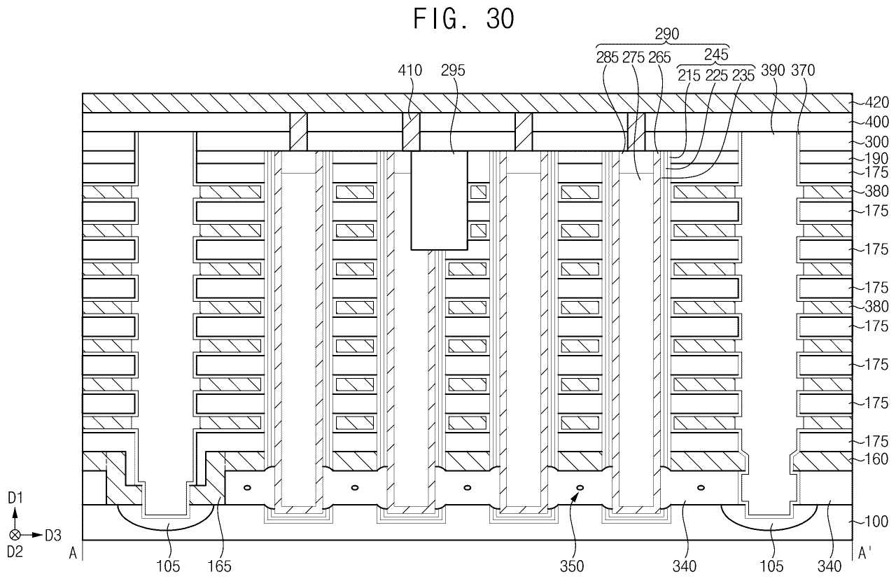

FIGS. 29 and 30 are cross-sectional views illustrating a vertical memory device in accordance with example embodiments, corresponding to FIGS. 1 and 2, respectively.

The vertical memory device may be substantially the same as or similar to a vertical memory of FIGS. 1 to 3, except for arrangement of the first channels 265 and location of the first division pattern 295, and thus, repeated explanations are omitted herein.

Referring to FIGS. 29 and 30, the first and second channel columns 265a and 265b may be alternately and repeatedly arranged along the third direction D3.

However, unlike the semiconductor device illustrated with reference to FIGS. 1 to 3, four of the first channel columns 265a and four of the second channel columns 265b may be alternately arranged with each other along the third direction D3 to form a channel group.

Hereinafter, four of the channel rows arranged along the third direction D3 from an imaginary center line, following the direction of the arrow pointing in the third direction D3, may be referred to as first, second, third and fourth channel columns 265a, 265b, 265c and 265d, respectively. Similarly, four of the channel rows arranged along the third direction D3 opposite to the direction of the arrow pointing in the third direction D3 from the imaginary center line may be referred to as first, second, third, and fourth channel columns 265a, 265b, 265c, and 265d, respectively.

In example embodiments, the first division pattern 295 may partially extend through upper portions of ones of the first channels 265, specifically, the first channels 265 of the first channel columns 265a of the channel group. That is, the first division pattern 295 may extend through upper portions of the first channel columns 265a facing each other in a plan view.

While example embodiments have been particularly shown and described, it will be understood by one of ordinary skill in the art that variations in form and detail may be made therein without departing from the scope of the claims.

1. A vertical memory device comprising:
a first channel on a substrate and extending in a vertical direction substantially perpendicular to an upper surface of a substrate;
a first charge storage structure comprising a first tunnel insulation pattern, a first charge storage pattern, and a first blocking pattern sequentially stacked on an outer sidewall of the first channel in a horizontal direction substantially parallel to the upper surface of the substrate; and
first gate electrodes spaced apart from each other in the vertical direction on the substrate and extending around the first charge storage structure,
wherein the first channel comprises silicon with a crystal structure in which {100} crystal planes are arranged in the vertical direction.

2. The vertical memory device of claim 1, wherein the first channel comprises a silicide of a metal.

3. The vertical memory device of claim 2, wherein the metal comprises at least one of nickel, cobalt, palladium, aluminum, gold, or silver.

4. The vertical memory device of claim 1, wherein the first channel comprises one of a plurality of first channels that are spaced apart from each other in the horizontal direction.

5. The vertical memory device of claim 4, further comprising:
a channel connection pattern in contact with the first channel,
wherein the first charge storage structure comprises an upper portion above the channel connection pattern and a lower portion below the channel connection pattern, relative to the upper surface of the substrate.

6. The vertical memory device of claim 4, further comprising:
a common source plate (CSP) in contact with a lower outer sidewall of the first channel,
wherein the first charge storage structure is on an upper outer sidewall of the first channel.

7. The vertical memory device of claim 1, wherein the first charge storage pattern comprises one of a plurality of first charge storage patterns that are spaced apart from each other in the vertical direction, and the first charge storage patterns face the first gate electrodes in the horizontal direction, respectively.

8. The vertical memory device of claim 1, further comprising:
a semiconductor pattern on the substrate,
wherein the first channel contacts a central portion of an upper surface of the semiconductor pattern, and the first charge storage structure contacts an edge portion of the upper surface of the semiconductor pattern.

9. The vertical memory device of claim 1, wherein the first channel and the first charge storage structure collectively form a first memory channel structure, and
wherein the first memory channel structure comprises a lower portion and an upper portion sequentially stacked in the vertical direction, each of the lower portion and the upper portion of the first memory channel structure has a respective width that gradually decreases toward the substrate, and an upper surface of the lower portion of the first memory channel structure has a width greater than a lower surface of the upper portion of the first memory channel structure.

10. The vertical memory device of claim 1, further comprising:
a second channel contacting an upper surface of the first channel and extending in a vertical direction;
a second charge storage structure on an outer sidewall of the second channel; and
a second gate electrode extending around the second charge storage structure.

11. The vertical memory device of claim 10, wherein the second channel comprises a lower portion having a first width, a middle portion having a second width and an upper portion having a third width, and each of the first and third widths are greater than the second width.

12. A vertical memory device comprising:
first memory channel structures on a substrate and extending in a first direction substantially perpendicular to an upper surface of the substrate, wherein the first memory channel structures are spaced apart from each other in a second direction and a third direction, the second direction being substantially parallel to the upper surface of the substrate, and the third direction being substantially parallel to the upper surface of the substrate and intersecting the second direction;
first gate electrodes spaced apart from each other in the first direction, the first gate electrodes extending around the first memory channel structures;
wherein the first memory channel structures respectively comprise:
a first channel on the substrate and extending in the first direction;
a first charge storage structure comprising a first tunnel insulation pattern, a first charge storage pattern, and a first blocking pattern sequentially stacked on an outer sidewall of the first channel in a horizontal direction substantially parallel to the upper surface of the substrate, and
wherein the first channels respectively included in the first memory channel structures respectively comprise silicon with a same crystal orientation.

13. The vertical memory device of claim 12, wherein the first channels respectively comprise silicon with a crystal structure in which {100} crystal planes are arranged in the first direction.

14. The vertical memory device of claim 12, wherein the first channels respectively comprise a silicide of a metal.

15. The vertical memory device of claim 14, wherein the metal comprises at least one of nickel, cobalt, palladium, aluminum, gold, or silver.

16. The vertical memory device of claim 12, wherein the plurality of the first channels of the first memory channel structures are spaced apart from each other in the second and third directions to form a channel array,
wherein the channel array comprises a first channel column and a second channel column, the first channel column comprising a subset of the first channels arranged along the second direction, the second channel column comprising a subset of the first channels arranged along the second direction, and the first and second channel columns are spaced apart from each other in the third direction, and
wherein the subset of the first channels of the first channel columns are oriented in a direction that forms an acute angle with the second direction or the third direction from the subset of the first channels of the second channel column.

17. The vertical memory device of claim 16, wherein the first channel column comprises a plurality of first channel columns and the second channel column comprises a plurality of second channel columns, wherein the first and second channel columns are alternately and repeatedly arranged in the third direction to form a channel group,
wherein the channel group comprises five of the plurality first channel columns and four of the plurality of second channel columns, and wherein the channel groups are spaced apart from each other in the third direction,
the vertical memory device further comprising a division pattern extending in the second direction through an upper portion of a third one of the first channel columns.

18. The vertical memory device of claim 16, wherein the first channel column comprises a plurality of first channel columns and the second channel column comprises a plurality of second channel columns, wherein the first and second channel columns are alternately and repeatedly arranged in the third direction to form a channel group,
wherein the channel group comprises four of the plurality first channel columns and four of the plurality of second channel columns, and a plurality of the channel groups are spaced apart from each other in the third direction,
further including a division pattern extending in the second direction through an upper portion of a third one of the first channel columns and an upper portion of a second one of the second channel columns.

19. A vertical memory device comprising:
memory channel structures on a substrate and extending in a first direction substantially perpendicular to an upper surface of the substrate, wherein the memory channel structures are spaced apart from each other in a second direction and a third direction, the second direction being substantially parallel to the upper surface of the substrate, and the third direction being substantially parallel to the upper surface of the substrate and intersecting the second direction;
gate electrodes spaced apart from each other in the first direction, the gate electrodes extending around the memory channel structures;
wherein the memory channel structures respectively comprise:
a channel on the substrate and extending in the first direction;
a charge storage structure comprising a tunnel insulation pattern, a charge storage pattern, and a blocking pattern sequentially stacked on an outer sidewall of the channel in a horizontal direction substantially parallel to the upper surface of the substrate,
wherein the channels respectively comprise single crystalline silicon in which {100} crystal planes are arranged in the first direction so that the channels respectively comprise silicon with a same crystal orientation, and at least one of the channels comprises a silicide of a metal.

20. The vertical memory device of claim 19, wherein the metal comprises at least one of nickel, cobalt, palladium, aluminum, gold, or silver.

21.-40. (canceled)
